(19) United States
(12) Patent Application Publication
(10) Pub. No.: US 2016/0043713 A1
(43) Pub. Date: Feb. 11, 2016

(54) DRIVE CIRCUIT FOR SEMICONDUCTOR SWITCHING ELEMENT AND SEMICONDUCTOR SWITCHING ELEMENT MODULE HAVING THE SAME

(71) Applicant: DENSO CORPORATION, Kariya-city (JP)

(72) Inventors: Shouichi OKUDA, Nukata-gun (JP); Yasutaka SENDA, Nukata-gun (JP)

(21) Appl. No.: 14/813,701

(22) Filed: Jul. 30, 2015

(30) Foreign Application Priority Data
Aug. 5, 2014 (JP) 2014-159447

(51) Int. Cl. H03K 17/30; H03K 17/567; H03K 17/082; H03K 5/24; H03K 17/14

(52) U.S. Cl. CPC H03K 17/302; H03K 5/24; H03K 17/145; H03K 17/0826; H03K 17/567; H03K 2017/0806

(57) ABSTRACT

In a drive circuit, a threshold voltage control device is activated when a mode determination circuit determines a specific mode switching signal. The threshold voltage control device controls a threshold voltage of a comparator through a threshold voltage setting device to be sequentially changed in a period where a semiconductor switching element is turned on in a state where a constant current is externally supplied between conduction terminals of the semiconductor switching element. The threshold voltage control device stores data corresponding to the threshold voltage of a time point where an output signal of the comparator changes due to the threshold voltage being changed to a nonvolatile storage. The threshold voltage control device reads out the threshold voltage from the storage and permits the threshold voltage setting device to set the threshold voltage read out to the comparator, when the mode determination circuit determines a drive control signal.

### CROSS REFERENCE TO RELATED APPLICATION

This application is based on Japanese Patent Application No. 2014-159447 filed on Aug. 5, 2014, the disclosure of which is incorporated herein by reference.

### TECHNICAL FIELD

The present disclosure relates to a drive circuit that provides a drive signal to a conduction control terminal of a semiconductor switching element according to a drive control signal received from an external device, and a semiconductor switching element module having the drive circuit and the semiconductor switching element.

### BACKGROUND

For example, in order to detect a current flowing through a semiconductor switching element, such as an insulated gate bipolar transistor (IGBT), it has been known to use an element having a main IGBT and a sensing IGBT for detecting the current. In general, the ratio of the current flowing in the main IGBT and the current flowing in the sensing IGBT largely varies. If the current detected by the sensing IGBT is directly used, a detection value also largely varies.

When an overcurrent protection of the main IGBT is carried out based on such a current largely varying, it is necessary to estimate the worst value of the current to a larger value. The element size of the IGBT needs to be selected to have a margin to breakdown according to the worst value. For example, JP 2013-198185 A, which corresponds to US 2013/0242438 A1, discloses an example of a structure for detecting overcurrent in a switching element.

### SUMMARY

For example, there is a method of correcting an overcurrent detection threshold set to a drive circuit according to a current value actually detected in each IGBT. In this case, however, it is necessary to control each IGBT and the drive circuit connected to each IGBT to have a relationship, and thus the control is complicated. Further, if the relationship between the IGBT and the drive circuit is erroneously made, it is difficult to correct the erroneous relationship later. Moreover, a measuring environment at the time of obtaining data and an operating environment when in use as a product may be different. Furthermore, the drive circuit may have variations in characteristics, and parasitic components due to the structure when the IGBT and the drive circuit are integrated as a module may occur. Such difference of the environments, the variation in the characteristics of the drive circuit, and the parasitic components may cause errors.

It is an object of the present disclosure to provide a drive circuit for a semiconductor switching element, which is capable of adjusting a threshold for suitably detecting overcurrent in a semiconductor switching element according to characteristics of an individual semiconductor switching element. It is another object of the present disclosure to provide a semiconductor switching module including the drive circuit and the semiconductor switching element.

According to a first aspect of the present disclosure, a drive circuit is for providing a drive signal to a conduction control terminal of a semiconductor switching element according to a drive control signal received from an external device through an input terminal. The drive circuit includes a comparator, a threshold voltage setting device, a nonvolatile storage, a mode determination circuit, and a threshold voltage control device. The comparator compares a voltage converted according to a current generated when the semiconductor switching element is turned on with a threshold voltage, and outputs an overcurrent detection signal. The threshold voltage setting device variably sets the threshold voltage. The nonvolatile storage stores data corresponding to the threshold voltage. The mode determination circuit determines whether an input signal received from the external device through the input terminal is the drive control signal or a specific mode switching signal. The threshold voltage control device is activated when the mode determination circuit determines that the input signal is the specific mode switching signal. The threshold voltage control device controls the threshold voltage through the threshold voltage setting device to be sequentially changed in a period where the semiconductor switching element is turned on in a state where a constant current is externally supplied between conduction terminals of the semiconductor switching element. The threshold voltage control device stores data corresponding to the threshold voltage of a time point where an output signal of the comparator changes due to the threshold voltage being changed in the storage. Further, the threshold voltage control device reads out the threshold voltage based on the data stored in the storage and permits the threshold voltage setting device to set the threshold voltage read out to the comparator, when the mode determination circuit determines that the input signal is the drive control signal.

In such a structure, when the mode switching signal is inputted in the state where the constant current can be supplied between the conduction terminals of the semiconductor switching element, the threshold voltage control device automatically determines a suitable threshold voltage according to the characteristics of the semiconductor switching element, and stores the threshold voltage determined to the storage. When the drive control signal is inputted, the threshold voltage control device reads out the threshold voltage from the storage and sets the threshold voltage to the comparator. Therefore, the threshold voltage for the overcurrent detection can be suitably set according to the characteristics of the semiconductor switching element actually used or an operating environment thereof.

According to a second aspect of the present disclosure, a drive circuit is for providing a drive signal to a conduction control terminal of a semiconductor switching element according to a drive control signal received from an external device through an input terminal. The drive circuit includes an A/D converter, a comparator, a nonvolatile storage, and a mode determination circuit. The A/D converter converts a voltage that has been converted according to a current generated when the semiconductor switching element is turned on into a digital data. The comparator compares the digital data with a threshold data, and outputs an overcurrent detection signal. The nonvolatile storage stores the threshold data. The mode determination circuit determines whether an input signal received from the external device through the input terminal is the drive control signal or a specific mode switching signal. When the mode determination circuit determines that the input signal is the specific mode switching signal, the storage stores the digital data converted through the A/D converter in a period where the semiconductor switching element is turned on in a state where a constant current is externally supplied between conduction terminals of the semiconductor switching element. When the input signal is the drive control signal, the comparator compares the digital data converted by the A/D converter and the threshold data stored in the storage.

In such a structure, when the mode switching signal is inputted in the state where the constant current can be supplied between the conduction terminals of the semiconductor switching element, a suitable threshold voltage according to the characteristics of the semiconductor switching element is automatically determined and stored in the storage. When the drive control signal is inputted, the threshold voltage stored in the storage is set to the comparator. Therefore, the threshold voltage for the overcurrent detection can be suitably set according to the characteristics of the semiconductor switching element actually used or an operating environment thereof.

### BRIEF DESCRIPTION OF THE DRAWINGS

The above and other objects, features and advantages of the present disclosure will become more apparent from the following detailed description made with reference to the accompanying drawings, in which like parts are designated by like reference numbers and in which:

FIG. 1 is a schematic block diagram of an IGBT module according to a first embodiment of the present disclosure;

FIG. 2A is a schematic block diagram of the IGBT module in a state where a scanning circuit performs a scanning operation;

FIG. 2B is a diagram illustrating a time chart in the scanning operation;

FIG. 3A is a waveform chart of a normal gate signal according to the first embodiment;

FIG. 3B is a waveform chart of an example of a mode switching signal according to the first embodiment;

FIG. 3C is a waveform chart of another example of the mode switching signal according to the first embodiment;

FIG. 4A is a schematic block diagram of a mode determination circuit of the IGBT module according to the first embodiment;

FIG. 4B is a diagram illustrating an internal clock signal and data patterns of the mode switching signal according to the first embodiment;

FIG. 5 is a flowchart illustrating a process including a scanning operation according to the first embodiment;

FIG. 6 is a schematic block diagram of an IGBT module according to a second embodiment of the present disclosure;

FIG. 7 is a time chart illustrating a writing high voltage applied to an input terminal of the IGBT module and an operation of a switch according to the second embodiment;

FIG. 8 is a schematic block diagram of an IGBT module according to a third embodiment of the present disclosure;

FIG. 9 is a flowchart illustrating a process including a scanning operation according to the third embodiment;

FIG. 10 is a schematic block diagram of an IGBT module according to a fourth embodiment of the present disclosure; and

FIG. 11 is a flowchart illustrating a process of a threshold data according to the fourth embodiment.

### DETAILED DESCRIPTION

### First Embodiment

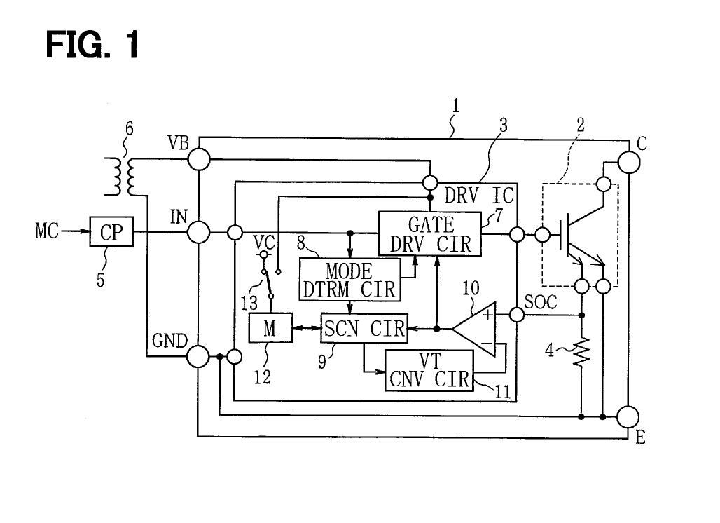

As shown in FIG. 1, an IGBT module 1 of the present embodiment is a module into which an IGBT 2 as a semiconductor switching element and a driver IC 3 as a drive circuit are integrated. A collector and an emitter of the IGBT 2 are respectively connected to external terminals C and E of the IGBT module 1. The IGBT 2 includes a sensing IGBT for sensing an electric current. An emitter of the sensing IGBT is connected to the external terminal E through a resistive element 4. The external terminal E is also connected to an external terminal GND inside of the IGBT module 1.

A gate control signal outputted from a microcomputer (MC) as a control device or an example of an external device is provided to an external terminal IN through a photo-coupler (CP) 5. Ends of a secondary winding of a transformer 6 are respectively connected to the external terminals VB and GND. A power supply voltage VB, which has been transformed based on a power supply (not shown) connected to a primary winding of the transformer 6, is supplied between the external terminal VB and the external terminal GND.

A gate drive circuit 7 is supplied with the power supply voltage VB. The gate drive circuit 7 receives the gate control signal through the terminal IN. The gate drive circuit 7 provides a gate drive signal to the gate of the IGBT 2. The gate control signal is also provided to a mode determination circuit 8. The mode determination circuit 8 determines whether the signal provided is a normal gate control signal or a mode switching signal that indicates a pattern different from that of the normal gate control signal. When determining that the signal provided is the mode switching signal, the mode determination circuit 8 activates a scanning circuit 9. The scanning circuit 9 corresponds to a threshold voltage control device.

A non-inverting input terminal of a comparator 10 is connected to the emitter of the sensing IGBT. An inverting input terminal of the comparator 10 is applied with a threshold voltage VT outputted from a VT conversion circuit 11. The VT conversion circuit 11 corresponds to a threshold voltage setting device. The VT transform circuit 11 is, for example, provided by a digital-to-analog (D/A) converter. The VT conversion circuit 11 outputs an analog voltage according to data provided from the scanning circuit 9, as the threshold voltage VT. An output of the comparator 10 is provided to the gate drive circuit 7 and the scanning circuit 9.

A memory (M) 12 is a non-volatile memory, such as EEPROM or a flash memory. Data can be written into or read out from the memory 12 by the scanning circuit 9. The memory 12 corresponds to a storage. The memory 12 can be selectively supplied with the power supply voltage VB or a control power supply voltage VC for reading out the data by means of a switch 13. The scanning circuit 19 controls the switching operation of the switch 13. The scanning circuit 19 controls the switch 13 so that the power supply voltage VB is supplied to the memory 12 when the data is written in the memory 12.

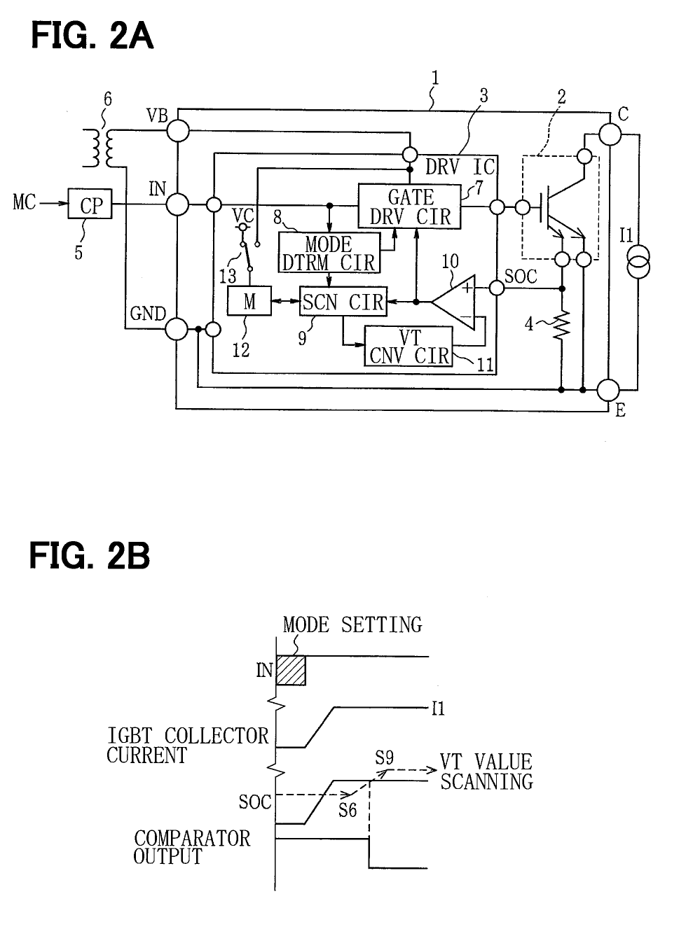

The driver IC 3 automatically obtains and sets an optimal value of the threshold voltage VT to the comparator 10 for overcurrent determination of the IGBT 2 as an object to drive. In such a case, as shown in FIG. 2A, a current source that generates a constant current I1 corresponding to a value that is determined as the overcurrent is connected beforehand between the external terminal C and the external terminal E of the IGBT module 1. As shown in FIG. 2B, after providing the mode switching signal to the terminal IN, the microcomputer provides the gate control signal being at a high level to the terminal IN to make the IGBT 2 in an on state. As a result, a collector current of the IGBT 2 begins to increase, and a terminal voltage SOC of the resistive element 4 also increases. In this state, the scanning circuit 9 is activated. The operation of the scanning circuit 9 will be described later in detail.

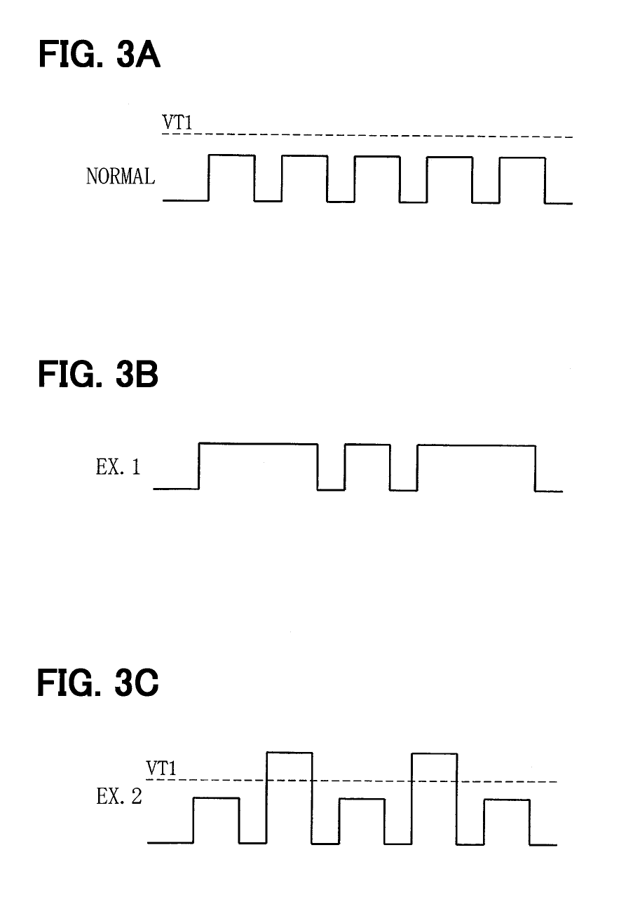

The mode switching signal is provided as a signal having a pattern that changes differently from the pattern of the normal gate control signal (PWM signal) shown in FIG. 3A. For example, the mode switching signal has an irregular cyclic pattern, differently from the carrier wave for the PWM control having a constant cycle, as shown by an example 1 of FIG. 3B. As another example, the mode switching signal has an irregular voltage amplitude, differently from the carrier wave for the PWM control having a constant voltage amplitude, as shown by an example 2 of FIG. 3C. In this case, the mode switching signal may have a pattern in which the amplitude exceeds a contact threshold voltage VT1 shown by a dashed line in FIG. 3C.

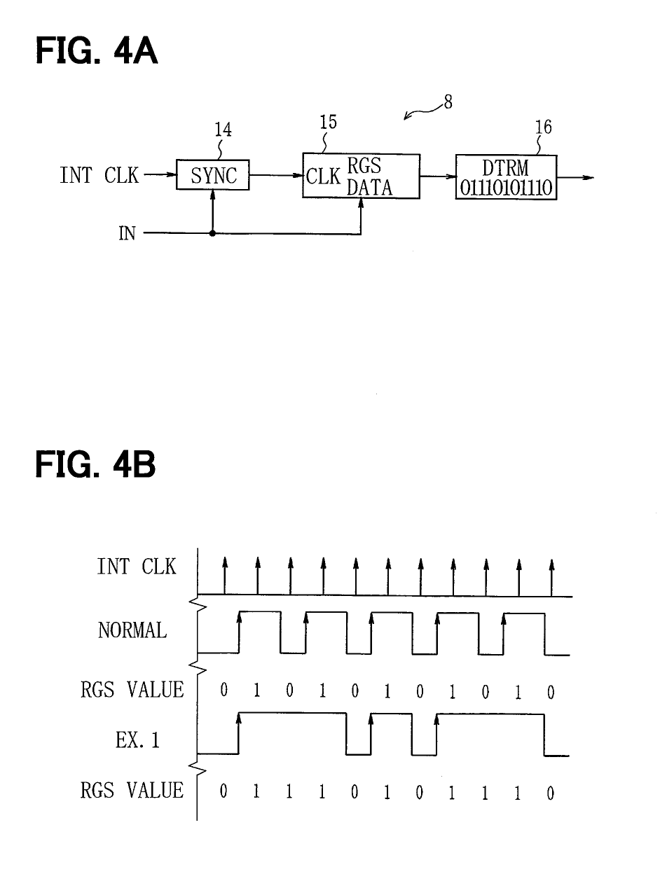

As shown in FIG. 4A, the mode determination circuit 8 includes a synchronous circuit 14, a register 15, and a determination portion 16. The synchronous circuit 14 receives the signal provided to the terminal IN and an internal clock signal CLK. The internal clock signal CLK has a frequency equal to or greater than twice the frequency of the PWM signal. The internal clock signal CLK is applied to a terminal CLK of the register 15 in a state of synchronizing with the signal provided to the terminal IN by means of the synchronous circuit 14.

A terminal DATA of the register 15 receives the signal provided to the terminal IN. In this example, the signal provided to the terminal IN is the mode switching signal having the irregular cyclic pattern shown in FIG. 3B. The signal has a data pattern of 11 bits indicating “01110101110” when reading at rising edges of the internal clock signal CLK. When this data is stored in the register 15, the determination portion 16 compares this data with a data pattern of the mode switching signal that is set beforehand. When the data coincides with the data pattern of the mode switching signal set beforehand, the determination portion 16 determines to switch the mode. Thus, the mode determination circuit 8 activates the scanning circuit 9.

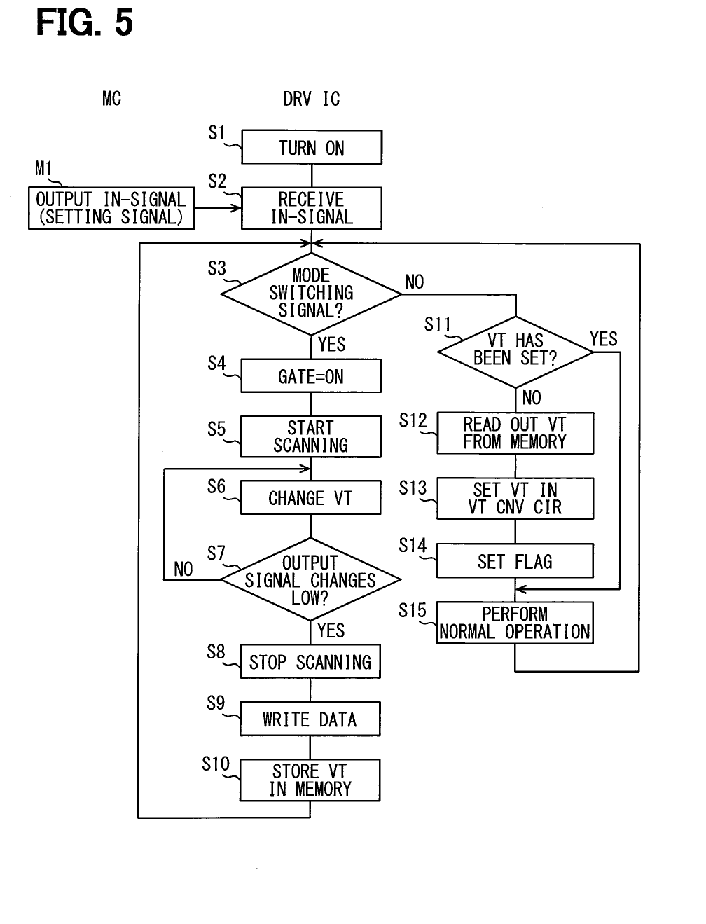

Next, an operation of the present embodiment will be described. As shown in FIG. 5, the driver circuit IC 3 is supplied with the electric power at S1. The driver circuit IC 3 is in a state of waiting for the signal inputted to the terminal IN (IN signal) from the microcomputer at S2. When the microcomputer outputs the IN signal at M1, the mode determination circuit 8 performs a mode determination at S3. When determining that the IN signal is the mode switching signal (S3: YES), the mode determination circuit 8 sets the gate of the IGBT 2 to the on level according to the gate control signal subsequently provided from the microcomputer at S4. Then, the scanning circuit 9 is activated to start a scanning operation of the threshold voltage VT at S5.

The scanning circuit 9 provides an initial value at first. At S6, the scanning circuit 9 changes the data of the threshold voltage VT inputted to the VT conversion circuit 11, and the VT conversion circuit 11 provides the analog threshold voltage VT to the inverting input terminal of the comparator 10 according to the data received. At S7, the scanning circuit 9 compares the change of the signal outputted from the comparator 10.

The initial value of the threshold voltage VT is set to a lower value. Since the IGBT 2 is turned on at S5, the collector current of the IGBT 2 is the constant current I1, and the terminal voltage of the resistive element 4 has a value corresponding to the current having a predetermined ratio to the constant current I1. As shown in FIG. 2B, therefore, the output signal of the comparator 10 indicates the high level at first.

In a period where the output signal of the comparator 10 is at the high level (S7: NO), the process returns to S6 and the scanning circuit 9 sequentially increases the threshold voltage VT. When the output signal of the comparator 10 changes from the high level to the low level (S7: YES), the scanning circuit 9 stops the scanning operation at S8. This is because the threshold voltage VT applied to the comparator 10 at the time point where the output signal changes from the high level to the low level is the value appropriate as the threshold for detecting the overcurrent. Therefore, in the normal operation, when the collector current, which is generated according to the switching operation of the IGBT 2, exceeds the current value I1, the output signal of the comparator 10 changes from the low level to the high level. As a result, the overcurrent is detected. In this case, the output signal of the comparator 10 changing from the low level to the high level corresponds to the output of the overcurrent detection signal.

When the overcurrent is detected, the gate drive circuit 7 keeps the IGBT 2 in the off state. During the scanning operation described above, the IGBT 2 needs to be kept in the on state even when the output signal of the comparator 10 is at the high level (see FIG. 2B). Therefore, the mode determination circuit 8 provides a signal for invalidating the overcurrent detection to the gate drive circuit 7. Next, the scanning circuit 9 writes data corresponding to the threshold voltage VT to the memory 12 to be stored at S9 and S10. Then, the process returns to S3.

When the IN signal is not the mode switching signal at S3 (S3: NO), the mode determination circuit 8 determines whether the threshold voltage VT has been set or not referring to a flag, which will be described later, at S11. When the threshold voltage VT has not been set (S11: NO), the scanning circuit 9 reads out the data corresponding to the threshold voltage VT stored in the memory 12 at S12, and sets the threshold voltage VT to the VT conversion circuit 11 at S13. When a flag indicating that the threshold voltage VT has been set is set at S14, the normal operation of the IGBT 2, that is, the switching control of the IGBT 2 according to the PWM signal is performed at S15. When it is determined that the threshold voltage VT has been set (S11: YES), the process proceeds to S15.

As described above, in the present embodiment, the driver IC 3 includes the VT conversion circuit 11 for setting the threshold voltage VT to be variable to the comparator 10 that outputs the overcurrent detection signal, and the memory 12 for storing the threshold voltage. The mode determination circuit 8 determines whether the signal inputted to the input terminal IN from an external device is the gate control signal or the specific mode switching signal.

The scanning circuit 9 is activated when the mode determination circuit 8 determines the mode switching signal being inputted. The scanning circuit 9 sets the threshold voltage VT to sequentially change through the VT conversion circuit 11 in the period where the IGBT 2 is in the on state in the state where the constant current I1 is externally supplied between the collector and the emitter.

When the output signal of the comparator 10 changes from the high level to the low level according to the change of the threshold voltage VT, the scanning circuit 9 stores the threshold voltage VT of the time point where the output signal of the comparator 10 changes from the high level to the low level in the memory 12. Thereafter, when the mode determination circuit 8 determines that the drive control signal is inputted, the scanning circuit 9 reads out the threshold voltage stored in the memory 12, and sets the threshold voltage read out to the comparator 10 through the VT conversion circuit 11. Therefore, the threshold voltage VT for the overcurrent detection can be properly set according to characteristics of the IGBT 2 actually used or an operating environment when the IGBT 2 is operated.

In the case where the mode switching signal has the frequency different from the frequency of the carrier wave of the PWM signal, the mode determination circuit 8 detects the change (difference) of the frequency. That is, the mode determination circuit 8 determines whether the signal has the specific data pattern. Therefore, the determination of the input of the mode switching signal is easily performed. In the case where the mode switching signal has the amplitude different from the amplitude of the PWM signal, the mode determination circuit 8 performs the determination by detecting the change (difference) of the amplitude, that is, by determining whether the amplitude exceeds the threshold voltage VT1. Also in this case, the determination of the input of the mode switching signal is easily performed.

### Second Embodiment

Hereinafter, components same or similar to those of the first embodiment will be designated with the same reference numbers, and descriptions thereof will not be repeated. Hereinafter, components different from the first embodiment will be mainly described.

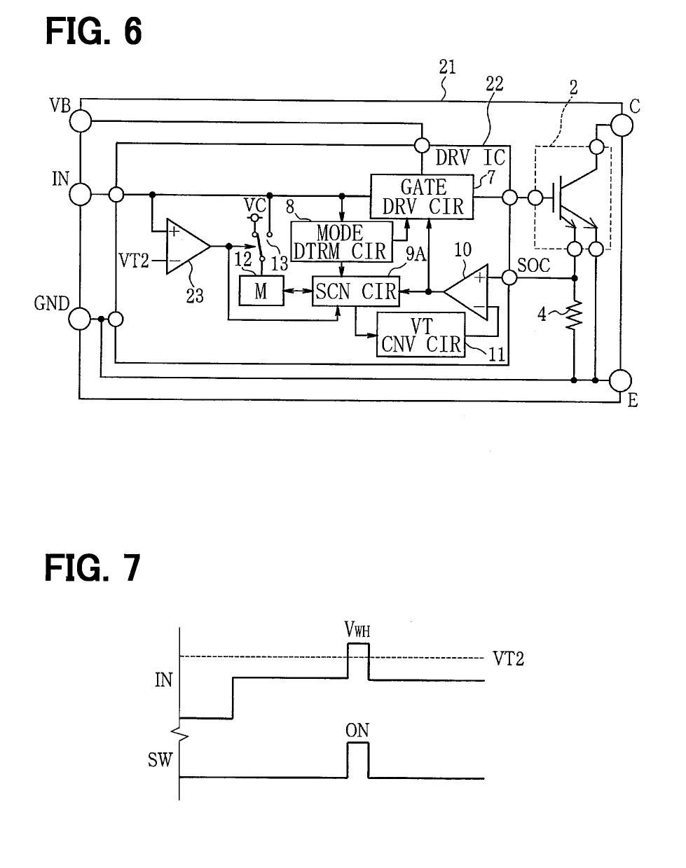

An IGBT module 21 of the second embodiment is supplied with the voltage for writing data (data-writing voltage) to the memory 12 of a driver IC 22 from the input terminal IN. Therefore, the driver IC 22 includes a comparator 23 for controlling the switch 13. In this case, the switch 13 corresponds to a selector, and the comparator 23 corresponds to a voltage switching control device. A non-inverting input terminal of the comparator 23 is connected to the input terminal IN, and an inverting input terminal of the comparator 23 is applied with a threshold voltage VT2. In FIG. 6, the illustration of the current source I1 is omitted.

A data-writing high voltage supplied to the memory 12 is higher than the threshold voltage VT2. As shown in FIG. 7, when the data-writing voltage V_{WH} is applied to the input terminal IN from an external device in a period where a scanning circuit 9A is performing the scanning operation (the IGBT 2 is kept in the on state), the output signal of the comparator 23 changes from the low level to the high level. Thus, the data-writing high voltage V_{WH} is supplied to the memory 12. The output signal of the comparator 23 is also applied to the scanning circuit 9A. Therefore, the scanning circuit 9A writes data corresponding to the threshold voltage VT to the memory 12 in the period where the data-writing high voltage is being supplied to the memory 12, based on the change of the output signal as the trigger.

In the second embodiment, as described above, the driver IC 22 includes the switch 13 to selectively input the voltage VC for the normal operation and the data-writing voltage to the memory 12, in the structure where the data-writing voltage for writing the data in the memory 12 is inputted to the input terminal IN. The comparator 23 detects the change of the voltage applied to the input terminal IN and controls the switch 13. Further, the comparator 23 provides the trigger to the scanning circuit 9A to write the data corresponding to the threshold voltage VT in the memory 12.

### Third Embodiment

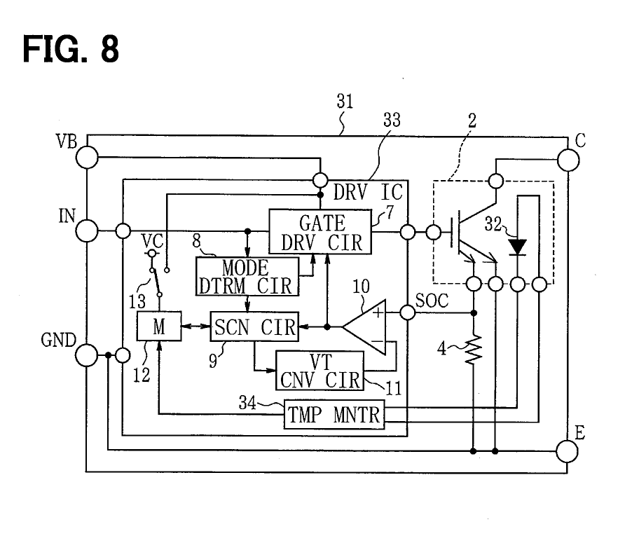

As shown in FIG. 8, an IGBT module 31 of a third embodiment includes a diode 32 for detecting the temperature of the IGBT 2, and a driver IC 33 includes a temperature monitoring portion 34. The diode 32 corresponds to a temperature detection device. The temperature monitoring portion 34 corresponds to the threshold voltage control device. An anode of the diode 32 is supplied with a constant voltage from the temperature monitoring portion 34. The temperature monitoring portion 34 detects the temperature of the IGBT 2 according to the change of a forward voltage of the diode 32. An output signal of the temperature monitoring portion 34 is provided to the memory 12 as a writing address. The temperature monitoring portion 34 assigns the writing address in regard to the forward voltage of the diode 32 every interval having some extent.

Next, an operation of the third embodiment will be described.

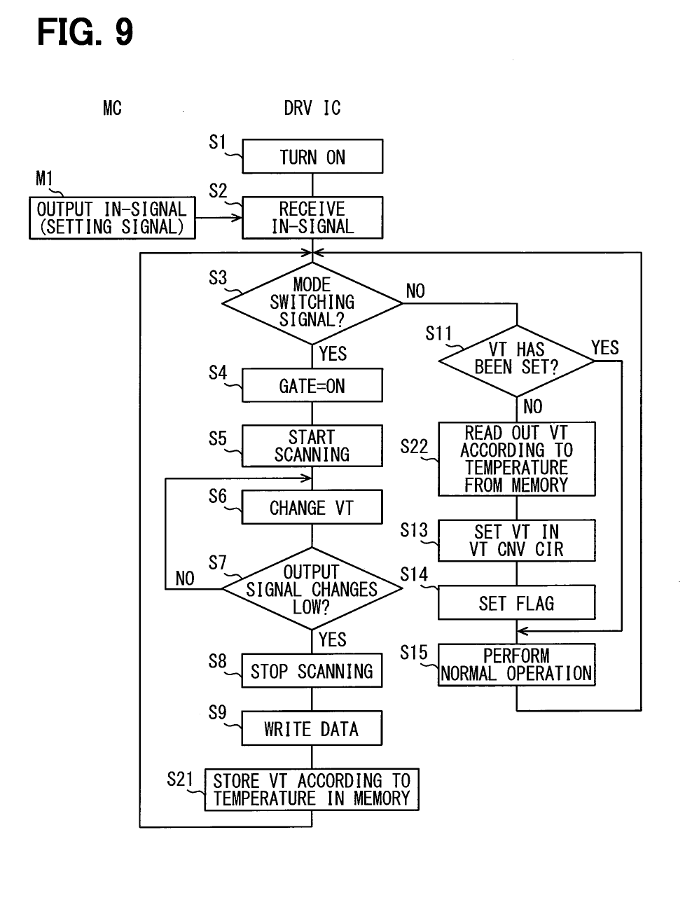

As shown in FIG. 9, the process includes S21 and S22, in place of S10 and S12 of the first embodiment. At S21, the threshold voltage VT is written in the memory 12. In this case, the threshold voltage VT is written in an address (writing region) according to the temperature of the IGBT 2 detected by the diode 32 at that time. This is because the value of the threshold voltage VT varies according to the temperature of the IGBT 2. Therefore, the writing of the data at S21 is performed several times while changing the temperature considering an assumed temperature in an operating environment when the IGBT module 31 is operated.

When it is determined that the threshold voltage VT has not been set at S11 (S11: NO), the threshold voltage VT is read out from the address of the memory 12 corresponding to the temperature of the IGBT 2 detected at that time at S22.

In the third embodiment, as described above, the IGBT module 31 includes the diode 32 for detecting the temperature of the IGBT 2. When the scanning circuit 9 stores the threshold voltage VT in the memory 12, the temperature monitoring portion 34 permits the threshold voltage VT to be stored in the storing region according to the temperature detected by the diode 32. When the mode determination circuit 8 determines the input of the gate control signal, the scanning circuit 9 reads out the threshold voltage VT according to the temperature detected by the diode 32 from the memory 12 and sets the threshold voltage VT to the comparator 10. Therefore, the threshold voltage VT according to the temperature of the operating environment of the IGBT 2 can be suitably set to the comparator 10.

### Fourth Embodiment

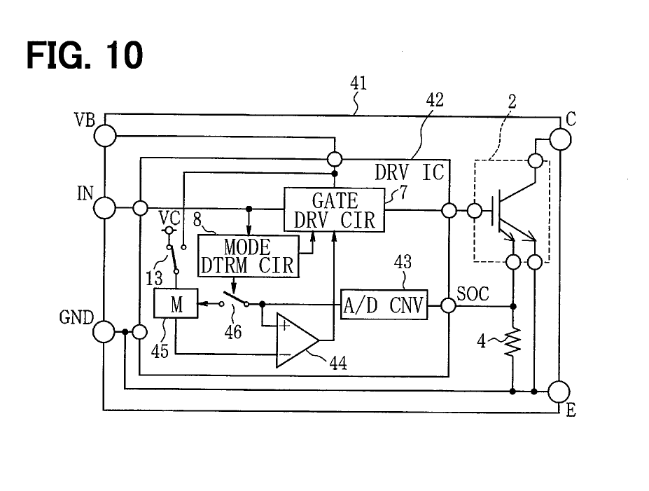

In an IGBT module 41 of a fourth embodiment, as shown in FIG. 10, a driver IC 42 is not provided with the scanning circuit 9, but is provided with an A/D converter 43 and a (digital) comparator 44. The driver IC 42 has a memory 45, in place of the memory 12. The memory 45 corresponds to the storage. An output terminal of the A/D converter 43 is connected to a (+) terminal of the comparator 44, and is also connected to an input terminal of the memory 45 through a switch 46.

When determining that the mode switching signal is inputted to the input terminal IN, the mode determination circuit 8 controls the switch 46 to turn on. In the other cases, that is, when the mode switching signal is not inputted to the input terminal IN, the mode determination circuit 8 controls the switch 46 to turn off. An output terminal of the memory 45 is connected to a (−) terminal of the comparator 44. The data written in the memory 45 is always applied to the (−) terminal of the comparator 44. An output terminal of the comparator 44 is connected to an input terminal of the gate drive circuit 7.

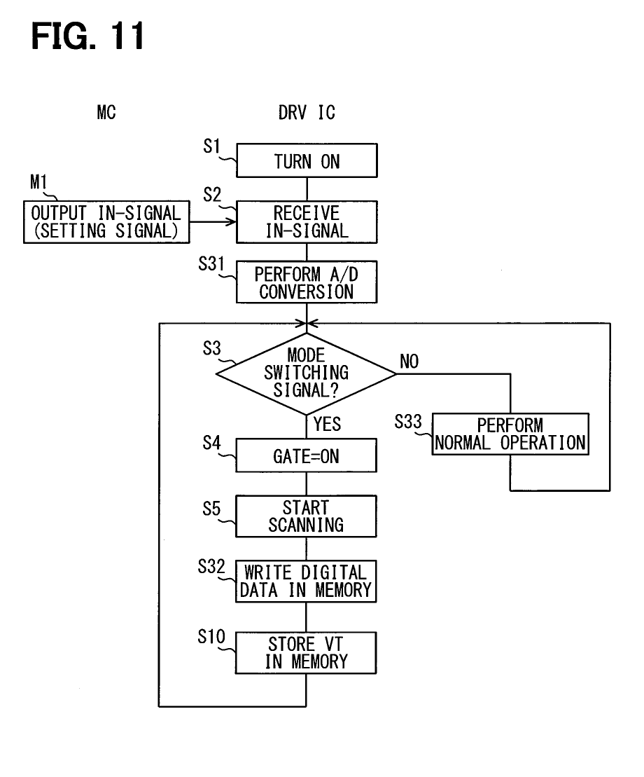

Next, an operation of the fourth embodiment will be described. As shown in FIG. 11, after S2 is performed, an analog-to-digital (A/D) conversion is performed by the A/D converter 43 at S31. The digital data converted at S31 is the terminal voltage when the constant current I1 is applied to the resistive element 4, and indicates an appropriate value as the threshold data for comparison in the comparator 44. Therefore, after S4 is performed, the digital data converted by the A/D converter 43 is written in the memory 45 at S32.

In the normal operation, which is determined as “NO” at S3, the comparator 44 compares the threshold data that is outputted from the memory 45 and is applied to the (−) terminal and the digital data converted by the A/D converter 43 at that time, thereby to detect the overcurrent, at S33.

In the fourth embodiment, as described above, the driver IC 42 includes the A/D converter 43 for converting the voltage converted according to the current flowing when the IGBT 2 is turned on into the digital data, and the memory 45 for storing the threshold data. When the mode determination circuit 8 determines the input of the mode switching signal, the memory 45 stores the data that is converted into the digital data by the A/D converter 43 as the threshold data in the period where the IGBT 2 is in the on state as the constant current I1 is externally supplied between the collector and the emitter.

In the state where the gate control signal is inputted to the input terminal IN from the external device, the comparator 44 compares the digital data converted by the A/D converter 43 and the threshold data stored in the memory 45. Therefore, similarly to the first embodiment, the threshold voltage for detecting the overcurrent can be suitably set according to the characteristics of the IGBT 2 actually used or the operating environment when in use. Further, the control process is further simplified, as compared with that of the first embodiment.

The present disclosure is not limited to the embodiments described hereinabove and illustrated in the drawings, but may be modified or extended as follows.

For example, the structure of the second embodiment and the structure of the fourth embodiment may be combined together.

The temperature detection device is not limited to the diode 32, but may be a thermistor or the like.

The storage device may include a fuse memory.

It is not always necessary that the IGBT 2 has the sensing IGBT.

In place of the resistive element 4, a current sensor may be used to detect a current and the current detected may be converted to a voltage signal.

It is not always necessary to integrate the IGBT 2 and the driver IC into the IGBT module. The IGBT and the driver IC may be configured as separate devices.

The semiconductor switching element is not limited to the IGBT 2, but may be a MOSFET or a bipolar transistor.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A drive circuit for providing a drive signal to a conduction control terminal of a semiconductor switching element according to a drive control signal received from an external device through an input terminal, the drive circuit comprising:
a comparator comparing a voltage converted according to a current generated when the semiconductor switching element is turned on with a threshold voltage, and outputting an overcurrent detection signal;
a threshold voltage setting device variably setting the threshold voltage;
a nonvolatile storage storing data corresponding to the threshold voltage;
a mode determination circuit determining whether an input signal received from the external device through the input terminal is the drive control signal or a specific mode switching signal; and
a threshold voltage control device:
being activated when the mode determination circuit determines that the input signal is the specific mode switching signal;
controlling the threshold voltage through the threshold voltage setting device to be sequentially changed in a period where the semiconductor switching element is turned on in a state where a constant current is externally supplied between conduction terminals of the semiconductor switching element;
storing data corresponding to the threshold voltage of a time point where an output signal of the comparator changes due to the threshold voltage being changed in the storage; and
reading out the threshold voltage based on the data stored in the storage and permitting the threshold voltage setting device to set the threshold voltage read out to the comparator, when the mode determination circuit determines that the input signal is the drive control signal.

2. The drive circuit according to claim 1, further comprising:
a temperature detecting device detecting a temperature of the semiconductor switching element, wherein
the threshold voltage control device stores the data corresponding to the threshold voltage in a predetermined storage region of the storage according to the temperature detected by the temperature detecting device, and
when the mode determination circuit determines that the input signal is the drive control signal, the threshold voltage control device reads out the data corresponding to the threshold voltage according to the temperature detected by the temperature detection device from the storage, and permits the threshold voltage read out to be set to the comparator.

3. The drive circuit according to claim 1, wherein
the mode switching signal has a frequency different from a frequency of the drive control signal, and
the mode determination circuit determines whether the input signal is the drive control signal or the specific mode switching element based on a change of the frequency.

4. The drive control circuit according to claim 1, wherein
the mode switching signal has an amplitude different from an amplitude of the drive control signal, and
the mode determination circuit determines whether the input signal is the drive control signal or the specific mode switching element based on a change of the amplitude.

5. The drive control circuit according to claim 1, wherein
the input terminal receives a data-writing voltage for writing data in the storage,
the drive control circuit further including:
a selector selectively inputting a voltage for a normal operation and the data-writing voltage in the storage; and
a voltage switching control device controlling the selector to switch between input of the voltage for the normal operation and input of the data-writing voltage, wherein
the voltage switching control device controls the selector to switch from the input of the voltage for the normal operation to the input of the data-writing voltage, when detecting that the input terminal receives the data-writing voltage.

6. A semiconductor switching element module comprising:
a semiconductor switching element; and
the drive circuit according to claim 1.

7. A drive circuit for providing a drive signal to a conduction control terminal of a semiconductor switching element according to a drive control signal received from an external device through an input terminal, the drive circuit comprising:
an A/D converter converting a voltage that has been converted according to a current generated when the semiconductor switching element is turned on into a digital data;
a comparator comparing the digital data with a threshold data, and outputting an overcurrent detection signal;
a nonvolatile storage storing the threshold data; and
a mode determination circuit determining whether an input signal received from the external device through the input terminal is the drive control signal or a specific mode switching signal, wherein
when the mode determination circuit determines that the input signal is the specific mode switching signal, the storage stores the digital data converted through the A/D converter in a period where the semiconductor switching element is turned on in a state where a constant current is externally supplied between conduction terminals of the semiconductor switching element, and
when the input signal is the drive control signal, the comparator compares the digital data converted by the A/D converter and the threshold data stored in the storage.

8. The drive circuit according to claim 7, wherein
the mode switching signal has a frequency different from a frequency of the drive control signal, and
the mode determination circuit determines whether the input signal is the drive control signal or the specific mode switching element based on a change of the frequency.

9. The drive control circuit according to claim 7, wherein
the mode switching signal has an amplitude different from an amplitude of the drive control signal, and
the mode determination circuit determines whether the input signal is the drive control signal or the specific mode switching element based on a change of the amplitude.

10. The drive control circuit according to claim 7, wherein
the input terminal receives a data-writing voltage for writing data in the storage,
the drive control circuit further including:
a selector selectively inputting a voltage for a normal operation and the data-writing voltage in the storage; and
a voltage switching control device controlling the selector to switch between input of the voltage for the normal operation and input of the data-writing voltage, wherein
the voltage switching control device controls the selector to switch from the input of the voltage for the normal operation to the input of the data-writing voltage, when detecting that the input terminal receives the data-writing voltage.

11. A semiconductor switching element module comprising:
a semiconductor switching element; and
the drive circuit according to claim 7.
